(19) United States
(12) Patent Application Publication
(10) Pub. No.: US 2025/0366209 A1
(43) Pub. Date: Nov. 27, 2025

(54) SEMICONDUCTOR STRUCTURE HAVING DUMMY REGIONS

(71) Applicant: Taiwan Semiconductor Manufacturing Company, Ltd., Hsinchu (TW)

(72) Inventors: Yi-Hui Chen, Changhua County (TW); Yi-Lii Huang, Hsinchu County (TW); Chih-Hsiao Chen, Taichung City (TW); Ming Chen Hung, Taichung City (TW); Yen Wei Tseng, Hsinchu County (TW); Yi-Chen Li, Taichung City (TW)

(21) Appl. No.: 19/286,470

(22) Filed: Jul. 31, 2025

Related U.S. Application Data
(63) Continuation of application No. 18/430,258, filed on Feb. 1, 2024.
(60) Provisional application No. 63/580,758, filed on Sep. 6, 2023.

(51) Int. Cl. H10D 89/10

(52) U.S. Cl. CPC H10D 89/10

(57) ABSTRACT

A semiconductor structure and a method of fabricating thereof including a substrate having a device region and a dummy region. A first active region is disposed over the substrate in the device region and a second active region is over the substrate in the dummy region. A first operational gate structure over the first active region and a first non-operational gate structure over the second active region. A first epitaxial region of an n-type dopant is adjacent the first operation gate structure; and a second epitaxial region of an n-type dopant is adjacent the first non-operational gate structure.

### PRIORITY

The present application is a continuation of U.S. patent application Ser. No. 18/430,258, filed Feb. 1, 2024, which claims priority to provisional application No. 63/580,758, filed Sep. 6, 2023, which are hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors, also referred to gate-all-around (GAA) devices, are examples of multi-gate devices that have become popular and promising candidates for high performance and low leakage applications. An MBC transistor has a gate structure that can extend, partially or fully, around a channel region to provide access to the channel region on two or more sides. Planar transistors may also be implemented for various performance considerations.

The semiconductor devices such as the transistors discussed above are active devices, which in some cases along with passive devices, are formed on device regions of a substrate. The substrate also includes dummy regions, which may not include functional devices. While existing technologies for fabricating semiconductor structures including device regions and dummy regions are generally adequate for their intended purposes, they have not been entirely satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of an exemplary method for designing a layout, according to various aspects of the present disclosure.

FIGS. 2A and 2B are fragmentary layouts of an exemplary semiconductor structure, according to various aspects of the present disclosure.

FIGS. 3A and 3B illustrate alternative embodiments of an enlarged portion of the layouts of FIG. 2B, according to various aspects of the present disclosure.

FIG. 4A is a fragmentary view of the layout of FIG. 2B, according to various aspects of the present disclosure. FIGS. 4B, 4C and 4D are exemplary embodiments of a semiconductor structure corresponding to the layout of FIG. 2B, according to various aspects of the present disclosure.

FIG. 5 is a top views of a layout of an embodiment of a semiconductor structure including device and dummy regions, according to various aspects of the present disclosure.

FIGS. 6-11 are each top views of a layout of an embodiment of a dummy region of a semiconductor structure, according to various aspects of the present disclosure.

FIG. 12 is a flow chart of an exemplary method for fabricating a semiconductor structure, according to various aspects of the present disclosure.

FIG. 13 is a block diagram of a system for implementing one or more aspects of the present disclosure including the method of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

In forming a semiconductor structure such as a semiconductor chip, active semiconductor devices such as transistors are formed on a substrate. The transistors may be planar transistors or multi-gate transistors, such as fin-type field effect transistors (FinFETs) or gate-all-around (GAA) transistors. The transistors are interconnected to form integrated circuits (IC). The transistors fabricated on the substrate may be p-type transistors or PMOS transistors (e.g., include p-type source/drain features) or n-type transistors or NMOS transistors (e.g., an n-type source/drain features). The PMOS and NMOS transistors are formed in device regions of the substrate. In particular, semiconductor structures include numerous oxide definition (OD) or active device areas on which transistors are formed. The OD region defines the active area for each transistor; that is, the area where the transistor's source/drain and channel are formed. The OD region is defined between isolation regions such as provided by shallow trench isolation (STI) or field oxide (FOX) areas.

The semiconductor structures are formed beginning with a design process. Computer aided design/electronic design automation (CAD/EDA) tools allow for such designing semiconductor devices. In some implementations, the circuit design process begins with a specification, which describes the desired functionality of the semiconductor structure (e.g., integrated circuit) and may include a variety of performance requirements. Then, in a logic design phase, logical implementation of the semiconductor structure is described using one of several hardware description languages (e.g., Verilog or VHDL at the register transfer logic (RTL) level of abstraction). The EDA software tool may synthesize the abstract logic into a technology dependent netlist using a library. The output can also describe the behavior of the circuits on the chip, as well as the interconnections to inputs and outputs.

After the logic design phase, the design proceeds to a physical design phase. The physical design creates a semiconductor structure design (e.g., a chip design). The physical design includes various steps including floor planning, place and routing, layout versus schematic (LVS) and design rule check (DRC) determinations. After a design of a semiconductor structure such as an integrated circuit chip is completed, a file (e.g., graphic data system (GDS) file) including the layout of the semiconductor structure is generated. The information is then provided (e.g., taped-out) to a fabrication facility. Masks defining the layers of the layout are then fabricated and used to fabricate the semiconductor structure itself. The present disclosure includes features that maybe represented in the layout during the design process.

One consideration in the design phase and the physical design phase in particular is across-chip uniformity. Certain semiconductor fabrication processes used to fabricate the chip according to the design introduce physical variations across the structure. The physical variations can lead to electrical performance and reliability issues. And as such, dummy regions are provided in the semiconductor structure (e.g., chip) that includes the active regions (e.g., comprising the active semiconductor devices such as transistor discussed above). The dummy regions may include components similar to the active regions (e.g., transistor features) that do not provide an electrical functionality to the semiconductor structure (e.g., are not interconnected). The dummy regions may mitigate any loading effects during patterning, etching, polishing, deposition, and/or other fabrication processes. The present disclosure provides for semiconductor structures, systems, and methods that define dummy regions. The present disclosure provides for design of dummy regions that may be formed on a substrate along with active regions.

In semiconductor structure design, a standard cell is a block of transistors that is repeated according to a set of design rules across a design layout. A standard cell may be used for different functions. For example, a standard cell may be a static random access memory (SRAM) cell or a logic cell for logic operations. A standard cell may include one or more p-type transistors and one or more n-type transistors. In some implementations, cells may also be formed that are dummy cells. The present disclosure includes dummy region layouts that may be provided as cells for implementing into a semiconductor structure as discussed below.

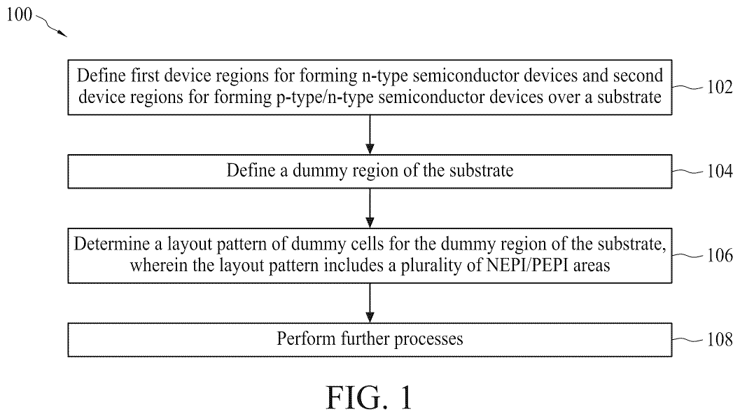

FIG. 1 illustrates a method 100 that may be implemented to form a semiconductor structure layout. In an embodiment, the semiconductor structure is a chip and in particular, an integrated circuit (IC) chip. The method 100 is merely exemplary and are not intended to limit the present disclosure to what is explicitly illustrated therein. Additional steps may be provided before, during and after the method 100, and some steps described can be replaced, eliminated, or moved around for additional embodiments of the methods. Not all steps are described herein in detail for reasons of simplicity.

In a first block 102, in a design process such as the physical design process discussed above, device regions are identified on the layout for the semiconductor structure. The device regions may include active devices of n-type transistors and p-type transistors. The transistors may be planar devices, FinFET devices, GAA devices, nanosheet devices, and/or suitable transistor configurations.

The method 100 and block 102 may be used to define a layout of semiconductor devices including, but are not limited to, active and passive devices. Examples of active devices include transistors including, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), FinFETs, GAA devices, nanosheet transistors (including as illustrated below), planar MOS transistors including those with raised source/drain, or the like. Other active devices include diodes. Examples of passive elements include, but are not limited to, capacitors, inductors, fuses, resistors, or the like. The layout may include interconnection features coupling one or more of the active and passive devices together, and to an input/output terminal of the semiconductor structure. The features of the semiconductor devices (e.g., gate structures) may be operational (e.g., contributing to the function of the device).

In a block 104 of the method 100, a dummy region of the substrate for the semiconductor structure is defined. Block 104 may be performed concurrently with block 102. The dummy region may include devices that do not provide electrical functionality to the semiconductor structure (e.g., IC chip). In other words, the features of the dummy region (e.g., gate structures) may be non-operational. The dummy region may include structures that are realized using substantially the same manufacturing processes as those of the device region. The dummy region(s) may be adjacent device regions.

In block 106, the method 100 continues to define the features within the dummy region of block 104. In some embodiments, the dummy region includes, for example, transistor features (e.g., OD regions, gate structures, source/drain regions) that are substantially the same as those features forming the transistors of the device region. In some further embodiments, the transistor features of the dummy region are not connected (e.g., lack contacts) such that they are not interconnected with one another and/or with an input/output (I/O) of the semiconductor structure (e.g., IC chip).

In particular, in some implementations, block 106 includes defining certain sub-regions of the dummy region that include dummy features substantially similar to an n-type transistor features and certain sub-regions of the dummy region that include dummy features substantially similar to a p-type transistor. For example, in some implementations, one or more sub-regions providing dummy features substantially similar to an n-type transistor such as n-type epitaxial (NEPI) regions are provided. The sub-region including these n-type transistor features (e.g., NEPI) may be referred to as NEPI regions. The NEPI regions may provide a source/drain region of a functional n-type transistor. The NEPI regions in fabrication of the chip are typically defined by a masking element that provides openings in the dummy region concurrently with providing openings in the device region, wherein the openings in the device region allow for forming source/drain features of the n-type transistors. The n-type epitaxial regions are formed on the OD or active regions exposed by the openings. In an embodiment, NEPI regions provide n-type epitaxial regions in the dummy region that are substantially similar to and formed at the same time as the source/drain regions of n-type transistors of the device region.

Further in block 106, in some implementations, one or more sub-regions providing dummy features substantially similar to a p-type transistor such as p-type epitaxial (PEPI) regions are also provided. The sub-region including these p-type transistor features (e.g., PEPI) may be referred to as PEPI regions. The PEPI regions in fabrication of the chip are typically defined by a masking element that provides openings in the dummy region concurrently with providing openings in the device region, wherein the openings in the device region allow for forming source/drain features of the p-type transistors. The p-type epitaxial regions are formed on the active or OD regions exposed by the openings. In an embodiment, PEPI regions provide p-type epitaxial regions in the dummy region that are substantially similar to and formed at the same time as the source/drain regions of p-type transistors of the device region.

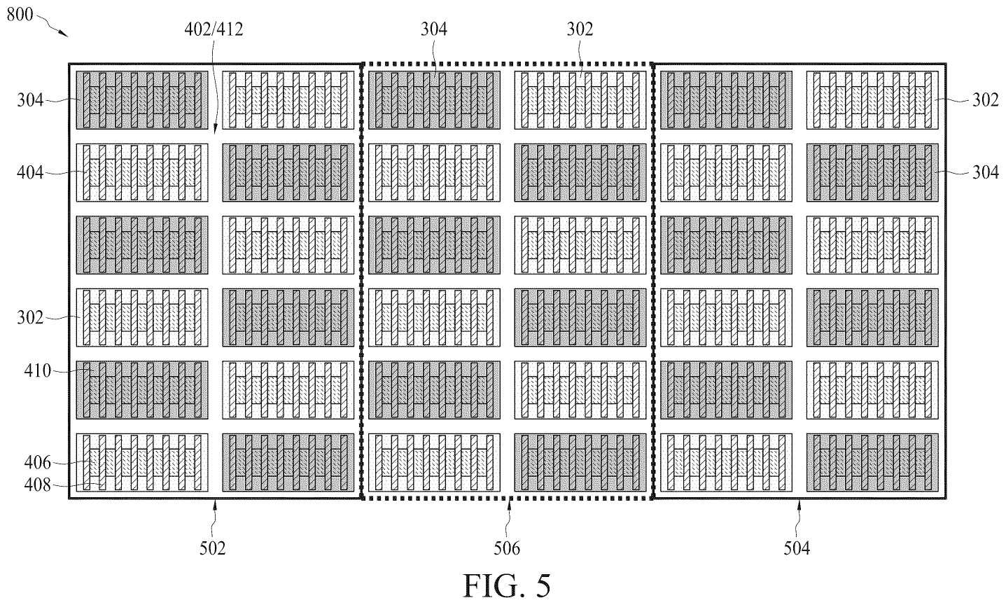

The configuration of the layout pattern of the dummy region including the location and quantity of NEPI regions and PEPI regions is selectively determined based on the features of the active region of block 102. For example, in some implementations, the number of NEPI regions in the dummy region is the same as the number of PEPI regions in the device region. In some implementations, the number of PEPI regions in the dummy region is the same as the number of NEPI regions in the device region. The layout pattern may be any of the patterns discussed herein including those of FIGS. 5-11 discussed below.

Block 108 then continues to perform further processes. The further processes may include additional design processes such as design rule checks, tape-out of the layout, fabrication of photomasks according to the layout and fabrication of the semiconductor structure according to the photomasks. The fabricated semiconductor structure may include a dummy region having a plurality of NEPI areas and in some implementations a plurality of NEPI areas and PEPI areas.

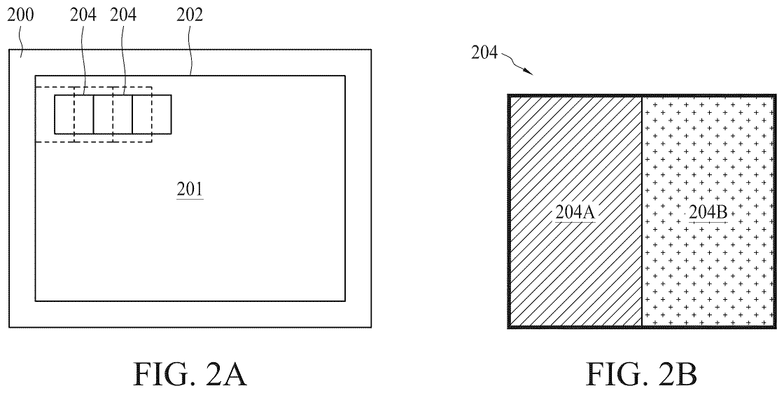

Referring to FIG. 2A, illustrated is a segment of a plan view of a semiconductor structure 200. The plan view includes a chip boundary region 202. The region between the edge of the chip 200 and the chip boundary region 202 may provide an exclusion area, which may not include any active or passive features semiconductor devices. A plurality of sub-regions 204 are formed on the semiconductor chip. The sub-regions 204 may be similar to one another. In an embodiment, various sub-regions 204 may patterned to include different features than one another. In an embodiment, the sub-regions 204 are formed by a same pattern. For reference purposes, the dashed line illustrates in an embodiment, a stepping field of a photolithography process. In some implementations, the stepper distance may be half of the sub-region 204 length in the x-direction. In an embodiment, the sub-regions define areas of approximately 18 μm by 18 μm in a fabricated device.

The sub-region 204 may include a device region 204A and a dummy region 204B as illustrated in FIG. 2B. The device region 204A may be defined as discussed above with reference to block 102 of the method 100. The dummy region 204B may be defined as discussed above with reference to block 104 of the method 100. Each of the device region 204A and the dummy region 204B include a plurality of OD or active regions on which semiconductor devices such as transistors are formed. For example, gate structures and source/drain features are form on the OD regions.

The device region 204A may include functional n-type transistors, e.g., include OD regions for n-type transistors, and functional p-type transistors, e.g., include OD regions for p-type transistors. The dummy regions 204B may include dummy OD regions corresponding to those formed in the device region 204A. In the illustrated embodiment, the dummy regions 204B are approximately the same in shape and size as the device region 204A. However, other configurations are possible. In some implementations, features in the device region 204A and the dummy regions 204B are realized using substantially the same manufacturing processes and have substantially the same internal structure.

The sub-region 204, and each of the device regions 204A and the dummy regions 204B, are not limited to the illustrated quadrangular top views, and for example, polygonal structures including triangular, pentagonal and octagonal structures and circular structures including an elliptical structure can be adopted without departing from the technical concept of the present invention. In an embodiment, all OD regions (dummy and device) may be greater than at least 10 percent of the structure (e.g., chip) 200.

When fabricated as semiconductor structure 200, a semiconductor substrate 201 is provided. In an embodiment, substrate 201 includes silicon. Alternatively or additionally, substrate 201 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. Alternatively, substrate 201 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

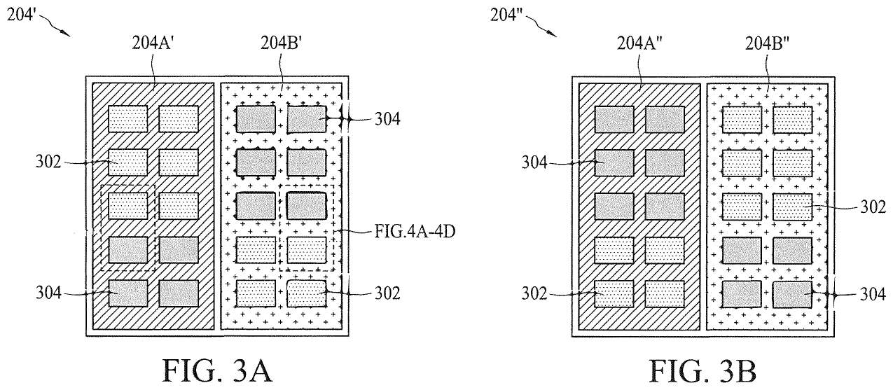

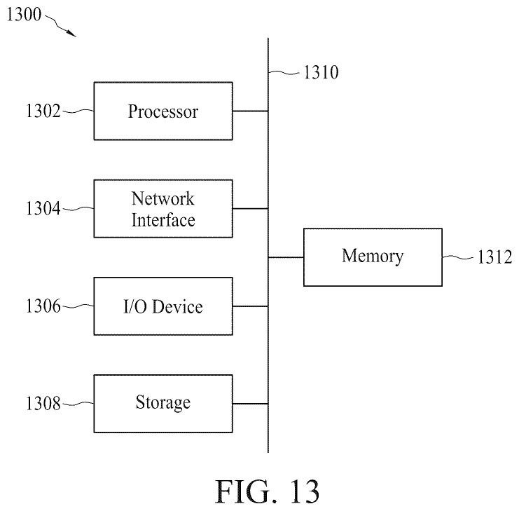

FIGS. 3A and 3B illustrate layout views of a portion of the semiconductor structure 200. The layout may be generated and stored using the method 100 of FIG. 1 and/or the system 1300 of FIG. 13. Generally in the present disclosure, the layout or plan views are also illustrative of a semiconductor structure corresponding to said layout as the layout will be fabricated into a semiconductor structure upon conclusion of the fabrication processes.

FIGS. 3A and 3B illustrate example sub-regions 204′ and 204″ respectively of a layout of a semiconductor structure. The sub-region 204′ includes a device region 204A′ and a dummy region 204B′, which may be substantially similar to as discussed above with reference to FIGS. 2A and 2B. The device region 204A′ includes a first plurality of NEPI regions 304 and a second plurality of PEPI regions 302. The NEPI regions 304 provide regions within which features of n-type transistors are formed such as an OD feature(s), gate structure(s), and a n-type doped source/drain(s) of a n-type transistor(s). The NEPI region 304 is also referred to as a cell. The PEPI regions 302 provide regions within which features of p-type transistors are formed such as an OD feature(s), gate structure(s), and a p-type source/drain(s) of a p-type transistor(s). The PEPI region 302 is also referred to as a cell. In an embodiment as illustrated, a three by two (row by column) arrangement of PEPI regions 302 and a two by two (row by column) arrangement of NEPI regions 304 are illustrated in the device region 204A′. Other implementations are also possible. In some implementations, the arrangement of PEPI regions and NEPI regions are dynamically regulated such that a ratio of PEPI to NEPI regions is regulated to achieve the desired device functionality and performance.

The NEPI regions 304 include the n-type epitaxial material and are defined by an edge of said n-type epitaxial material. The PEPI regions 302 include the p-type epitaxial material and are defined by an edge of said p-type epitaxial material. In some implementations of the fabrication of the semiconductor structure, the PEPI regions 302 are defined by a first masking element during the fabrication of the structure 200. That is, while a masking element covers the remainder of the structure, openings in the masking element—the PEPI regions 302—are provided and p-type epitaxial structures are fabricated on the exposed OD regions. And in some implementations, the NEPI regions 304 are defined by another masking element during the fabrication of the structure 200. That is, while a masking element covers the remainder of the structure, openings in the masking element—the NEPI regions 304—are provided and n-type epitaxial structures are fabricated on the exposed OD regions.

The dummy region 204B′ includes a first plurality of NEPI regions 304 and a second plurality of PEPI regions 302. The NEPI regions 304 may be substantially similar to those regions in the device region 204A′. That is the NEPI regions 304 in the dummy region 204B′ provide regions configured substantially similar to the NEPI regions 304 including source/drain of the transistors of the device region 204A′. The PEPI regions 302 provide p-type regions. The PEPI regions 302 of the dummy region 204B′ may be substantially similar to the PEPI regions 302 of the device region 204A′. That is the PEPI regions 302 of the dummy region 204B′ provide p-type regions configured substantially similar to the PEPI regions 302 providing the source/drain of the transistors of the device region 204A′. In an embodiment as illustrated, a three by two (row by column) arrangement of NEPI regions 304 and a two by two (row by column) arrangement of PEPI regions 302 are provided in the dummy region 204B′.

In the illustrated embodiment, the configuration of NEPI regions and PEPI regions from the device region 204A′ to the dummy region 204B′ is reversed or swapped. In an embodiment, the number of NEPI regions 304 in the device region 204A′ may be equal to the number of PEPI regions 302 of the dummy region 204B′. In an embodiment, the number of PEPI regions 302 in the device region 204A′ may be equal to the number of NEPI regions 304 of the dummy region 204B′.

Turning now to the embodiment of FIG. 3B, the sub-region 204″ includes a device region 204A″ and a dummy region 204B″. The device region 204A″ includes a first plurality of NEPI regions 304 and a second plurality of PEPI regions 302. The NEPI regions 304 and PEPI regions 302 may be substantially similar to as discussed with reference to FIG. 3A. However, in an embodiment as illustrated in FIG. 3B, a three by two (row by column) arrangement of NEPI regions 304 and a two by two (row by column) arrangement of PEPI regions 302 are provided in the device region 204A″. And a three by two (row by column) arrangement of PEPI regions 302 and a two by two (row by column) arrangement of NEPI regions 304 are provided in the dummy region 204B″. In the illustrated embodiment of FIG. 3B, the configuration of NEPI and PEPI regions from the device region 204A″ to the dummy region 204B″ is reversed or swapped. In an embodiment, the number of NEPI regions 304 in the device region 204A″ may be equal to the number of PEPI regions 302 of the dummy region 204B″. In an embodiment, the number of PEPI regions 302 in the device region 204A″ may be equal to the number of NEPI regions 304 of the dummy region 204B″.

In some implementations, the selection of the number and configuration of the NEPI regions 304 and/or the PEPI regions 302 of the dummy region 204B″ and/or dummy region 204B′ may be performed as part of block 106 of the method 100. That is, the dummy region 204B′/204B″ configuration may be dynamically regulated based on the determined layout of the active region 204A′/204A″. In some implementations, the distribution of NEPI and PEPI regions in the dummy region allows for converging EPI critical dimension (CD) distribution between the devices of the semiconductor structure (e.g., chip). As discussed above, the NEPI and PEPI regions may be defined by a masking element formed in a photolithography process during the fabrication of a semiconductor substrate corresponding to the layouts of sub-regions 204′ and 204″. An open ratio of the mask element providing the NEPI opening affects the NEPI CD. That is, a small open ratio for NEPI (e.g., lower number of NEPI regions) can provide for a larger NEPI CD.

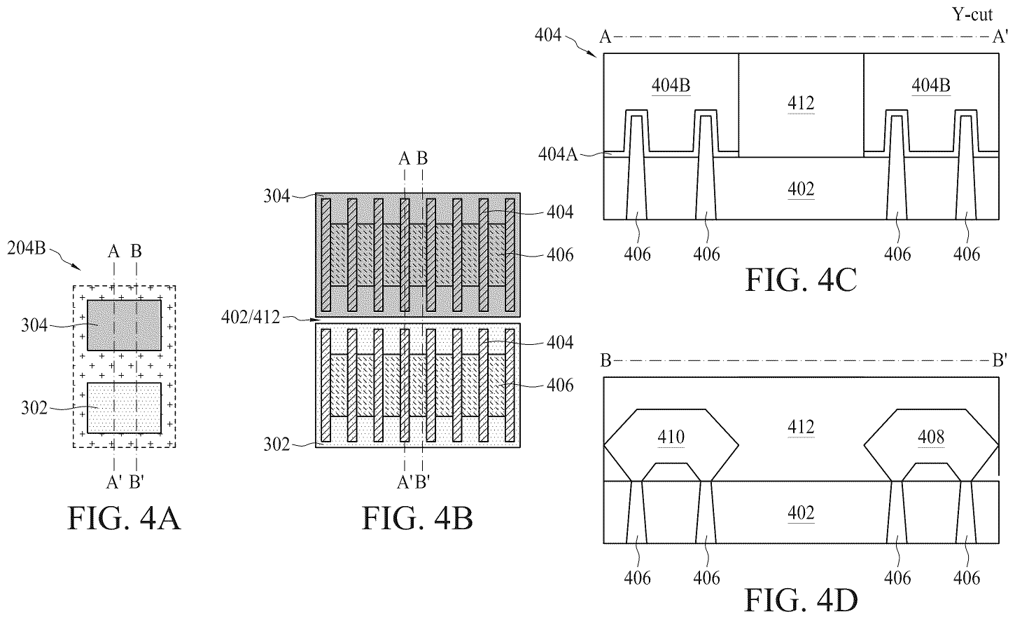

Further description applicable to the sub-regions 204, 204′, 204″ discussed above with reference to FIGS. 2A, 2B, 3A, and 3B are provided with respect to FIGS. 4A-4D. In particular, FIGS. 4A-4D illustrate an embodiment of a dummy region 204B of the sub-region 204. The dummy region 204B may be substantially similar to the dummy region 204B discussed above with reference to FIGS. 2B, 3A, and 3B. In implementations, transistors formed in the dummy region 204B do not provide functionality to the formed structure (e.g., are not interconnected), while the transistors formed in the device region 204A are interconnected to form the IC functionality of the structure (e.g., chip).

FIG. 4A shows a plan view of a portion of the dummy region 204B illustrating a first sub-region 302 and a second sub-region 304. The first sub-region 302 is an PEPI region. The second sub-region 304 is a NEPI region. The NEPI region is defined for n-type transistors (e.g., dummy n-type transistors). The PEPI region is defined for p-type transistors (e.g., dummy p-type transistors).

FIG. 4B illustrates a top view of a corresponding layout view of the dummy region 204B illustrating the first type of sub-region 302 and the second type of sub-region 304. In an embodiment, the first sub-region 302 is the PEPI region and the second sub-region 304 is the NEPI region. Between the sub-regions 302 and 304 may be isolation features such as the isolation features 402 and 412 discussed below.

As shown in FIG. 4B, a plurality of gate structures 404 extend in a y-direction in the top view. In some implementations, the gate structures 404 of the sub-region 304 are substantially collinear with the gate structures 404 of the sub-region 302. In an embodiment, a dielectric region 412 interposes the gate structures 404 of the sub-region 302 and the gate structures 404 of the sub-region 304 (see FIG. 4C). The gate structures 404 extend over the respective OD regions 406. In some implementations as shown in FIG. 4B, the OD region 406 extends in the x-direction in the top view.

In an embodiment, such as illustrated in FIGS. 4C and 4D, the OD region 406 is comprised of fin elements. Fin elements extend vertically from a top surface of the substrate (e.g., z-direction) and provide a channel region accessible from multiple sides and a top surface. In a top view, the fin elements may extend in an x-direction substantially perpendicular to the gate structures 404. In other embodiments, the OD region 406 includes a planar semiconductor substrate region. In other embodiments, the OD region 406 includes a plurality of nanowire or nanosheets providing channel regions. In an embodiment, the OD regions 406 are silicon. However, other semiconductor materials including as discussed below with respect to a substrate may additionally or alternatively be implemented.

Between OD regions 406 are isolation features 402. These isolation regions may also be referred to as a shallow trench isolation (STI) features. In some embodiments, the isolation feature 402 may include silicon oxide, silicon nitride, silicon oxynitride, fluorine-doped silicate glass (FSG), a low-k dielectric, combinations thereof, and/or other suitable materials. The isolation features 402 may include a multi-layer composition. Exemplary deposition processes include low-pressure CVD (LPCVD), CVD, plasma-enhanced CVD (PECVD), PVD, atomic layer deposition (ALD), thermal oxidation, e-beam evaporation, or other suitable deposition techniques, or combinations thereof.

Between gate structures 404, epitaxial regions are formed over the OD regions 406. The epitaxial regions are substantially similar to those of NEPI region 304 and PEPI region 302 discussed above including that the epitaxial regions correspond to the source/drain features of a transistor. As illustrated in FIG. 4D, epitaxial layers 410 and 408 are formed over the OD regions 406. In an embodiment, the epitaxial features 408 are p-type dopant material; and the epitaxial features 410 are n-type dopant material. Suitable epitaxial processes for forming the p-type epitaxial features 408 include CVD deposition techniques (e.g., vapor-phase epitaxy (VPE) and/or ultra-high vacuum CVD (UHV-CVD)), molecular beam epitaxy (MBE), and/or other suitable processes. The epitaxial growth process may use gaseous and/or liquid precursors, which interact with the composition of the OD region 406. When forming the p-type epitaxial regions 408 in the PEPI region 304, the NEPI region 302 may be masked. In various embodiments, the p-type epitaxial features 408 may include Si, Ge, AlGaAs, SiGe, boron-doped SiGe (SiGeB), or other suitable material. The p-type epitaxial features 408 may be in-situ doped during the epitaxial process by introducing doping species including p-type dopants, such as boron or BF₂, and/or other suitable dopants including combinations thereof. In some implementations, an implantation process may be performed to dope the p-type epitaxial features 408. The p-type epitaxial features 408 are configured substantially similar to the source/drain features of the p-type transistors in the device region 204A, but are not connected.

After forming the p-type epitaxial features 408, a patterned pattern film covering the NEPI region 304 may be removed. Another patterned pattern film (not explicitly shown) may be then formed to cover the PEPI region 302. Suitable epitaxial processes for forming n-type dopant epitaxial features 410 may be similar to the epitaxial processes for forming p-type epitaxial features 408. In various embodiments, the n-type epitaxial features 410 may include Si, GaAs, GaAsP, SiP, or other suitable material. The n-type epitaxial features 410 may be in-situ doped during the epitaxial process by introducing doping species including n-type dopants, such as phosphorus or arsenic; and/or other suitable dopants including combinations thereof. In some implementations, an implantation process may be performed to dope the n-type epitaxial features 410. The n-type epitaxial features 410 are configured substantially similar to the source/drain features of the n-type transistors in the device region 204A, but are not connected.

Isolation regions 412 interpose the epitaxial features 408, 410 (FIG. 4D) as well as the gate structures 404 (FIG. 4C). In an embodiment, the isolation region 412 may include a contact etch stop layer (CESL) and/or an interlayer dielectric (ILD) layer. The CESL may include silicon nitride, silicon oxide, silicon oxynitride, and/or other materials known in the art and may be formed by ALD, plasma-enhanced chemical vapor deposition (PECVD) process and/or other suitable deposition or oxidation processes. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer may be deposited by a PECVD process or other suitable deposition technique.

The gate structure 404 includes gate dielectric layer 404A and gate electrode 404B. In an exemplary process, a gate dielectric layer 404A is first formed and the gate electrode 404B is deposited over the gate dielectric layer. In an embodiment, the gate structure 404 is a polysilicon gate providing an electrode 404B of polysilicon. In some implementations, the gate dielectric layer 404A may be silicon oxide.

In some other embodiments, the gate structure 404 may be high-k metal gate structure formed using a dummy gate structure (e.g., poly gate discussed above) that is subsequently replaced through a replacement gate process. In some embodiments, the gate dielectric layer 404A may include an interfacial layer and a high-k dielectric layer. High-K gate dielectrics, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be deposited using chemical oxidation, thermal oxidation, ALD, CVD, and/or other suitable method. The high-K dielectric layer may include hafnium oxide, titanium oxide, hafnium zirconium oxide, tantalum oxide, hafnium silicon oxide, zirconium silicon oxide, lanthanum oxide, aluminum oxide, zirconium oxide, yttrium oxide, SrTiO₃ (STO), BaTiO₃ (BTO), BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The high-K dielectric layer may be formed by ALD, physical vapor deposition (PVD), CVD, oxidation, and/or other suitable methods. The gate electrode 404B of the gate structure 404 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. In various embodiments, the gate electrode 404B may be formed by ALD, PVD, CVD, e-beam evaporation, or other suitable process. The gate electrode 404B may include an n-type work function metal layer or a p-type work function metal layer corresponding to the functionality of device. The n-type work function metal layer may include Ti, Al, Ag, Mn, Zr, TiAl, TiAlC, TaC, TaCN, TaSiN, TaAl, TaAlC, TiAlN, other n-type work function material, or combinations thereof. A p-type function metal layer such as TiN, TaN, Ru, Mo, Al, WN, ZrSi₂, MoSi₂, TaSi₂, NiSi₂, WCN, other p-type work function material, or combinations thereof.

In some implementations, a contact is formed to one or more of the gate electrode or source/drain features.

Referring now to FIG. 5, illustrated is a configuration of a layout of a semiconductor structure 500. The semiconductor structure 500 of FIG. 5 may be a portion of a semiconductor structure such as chip 200, described above with reference to FIGS. 2A and 2B. Illustrated in FIG. 5 are a first device region 502 and a second device region 504. A dummy region 506 interposes the first device region 502 and the second device region 504. The first and second device regions 502, 504 may be substantially similar to the device region 204A discussed above. The first and second device regions 502, 504 include a plurality of functional semiconductor device such as n-type and p-type transistors. Each device region 502, 504 includes a plurality of NEPI regions or n-type transistor cells 304 and a plurality of PEPI regions or p-type transistor cells 302. The NEPI regions 304 and PEPI regions 302 may be substantially similar to as discussed. A plurality of gate structures 404 extend in a y-direction and OD regions 406 extend in an x-direction. As discussed above, the OD regions 406 may be planar substrate regions, fin elements, nanowires or nanosheets, and/or other channel configurations. Epitaxial features 410 provide the source/drain features in the NEPI regions 304; epitaxial features 408 provide the source/drain features in the PEPI regions 302. Isolation structures 402/412 interpose the PEPI regions 302 and NEPI regions 304 and/or interpose portions of the OD regions 406.

As illustrated in FIG. 5, each of the device regions 502 and 504 include an equal number of NEPI regions 304 and PEPI regions 302. And each of the device regions 502 and 504 have an array of NEPI regions 304 and PEPI regions 302 where the array has alternating NEPI regions 304 and PEPI regions 302.

The dummy region 506 interposing the first device region 502 and the second device region 504 also includes a plurality of NEPI regions or cells 304 and a plurality of PEPI regions or cells 302. The dummy region 506 may be substantially similar to the dummy region 204B discussed above. The dummy region 506 include not include functional semiconductor devices such as n-type and p-type transistors, but rather include features configured substantially similar to the transistors without connection. The NEPI regions 304 and PEPI regions 302 may be substantially similar to as discussed above with respect to FIGS. 4A-4D. A plurality of gate structures 404 extend in a y-direction and OD regions 406 extend in an x-direction. As discussed above, the OD regions 406 may be planar substrate regions, fin elements, nanowires or nanosheets, and/or other channel configurations. Epitaxial features 408 provide the epitaxial features in the PEPI regions 302; epitaxial features 410 provide the epitaxial features in the NEPI regions 304. Isolation structures 402/412 interpose the PEPI regions 302 and NEPI regions 304 and/or interpose portions of the OD regions 406. While the OD regions 406, gate structures 404, and epitaxial features 408/410 are substantially similar to those transistor components of the device regions 502, 504, the features do not form an active transistor in the dummy region 506 as they are not connected to other transistors and/or I/O.

As illustrated in FIG. 5, the dummy region 506 includes an equal number of NEPI regions 304 and PEPI regions 302. And dummy region 506 has an array of NEPI regions 304 and PEPI regions 302 where the NEPI regions 304 and PEPI regions 302 are alternating. In an embodiment as illustrated, the dummy region 506 has the same configuration as the device regions 502 and/or 504.

In an embodiment of the layout, all OD regions are greater than approximately 10% of the semiconductor (e.g., chip) area.

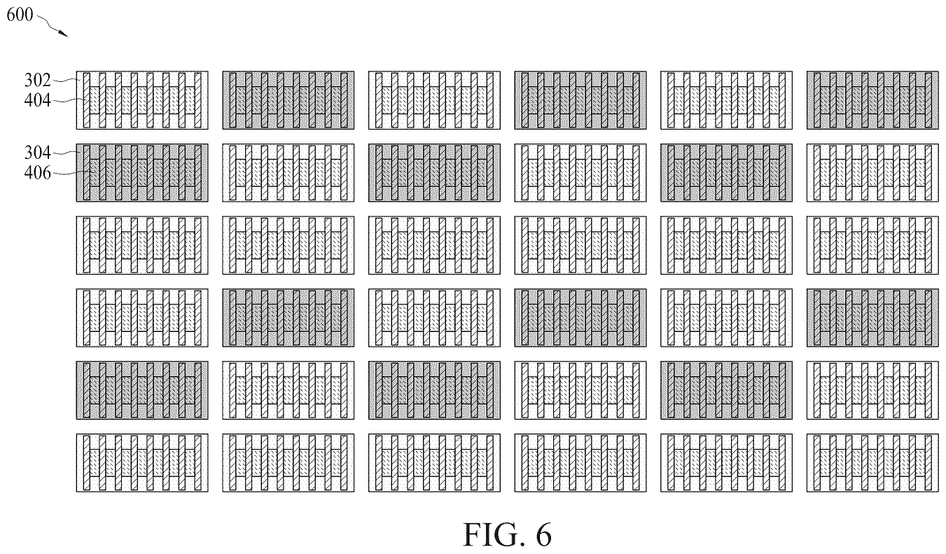

FIGS. 6-11 illustrate example layout views of a dummy region of a semiconductor structure. The dummy regions may be substantially similar to the regions 204B of FIGS. 2B, 3A, 3B, 4A, 4B, 4C, and 4D and/or dummy region 506 of FIG. 5. The layout of the dummy region includes NEPI regions 304 and PEPI regions 302. Each of the NEPI regions 304 and PEPI regions 302 include a plurality of gate structures 404 extending in a y-direction and OD regions 406 that said gate structures 404 extend over. The NEPI region 304 include n-type epitaxial regions such as epitaxial regions 410 discussed above with respect to FIG. 4D. The PEPI region 302 include p-type epitaxial regions such as epitaxial regions 408 discussed above with respect to FIG. 4D.

In FIG. 6, the layout 600 illustrates a dummy region having a first plurality of PEPI regions 302 and a second plurality of NEPI regions 304. The first plurality of PEPI regions 302 is greater in number than the second plurality of NEPI regions 304. In an embodiment, the ratio of PEPI regions 302 to NEPI region 304 is 2:1. In an embodiment, a device region adjacent the dummy region of the layout 600 may include a NEPI region 304 to PEPI region 302 ratio of 2:1, with the NEPI and PEPI configuration swapped in array positions between the device region and the dummy region.

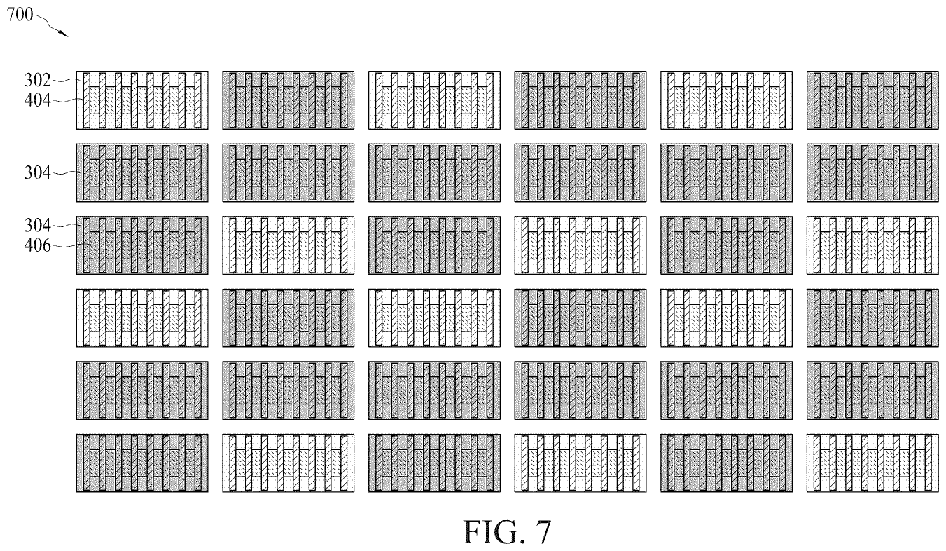

In FIG. 7, the layout 700 illustrates a dummy region having a first plurality of PEPI regions 304 and a second plurality of NEPI regions 302. The first plurality of NEPI regions 304 is greater in number than the first plurality of PEPI regions 302. In an embodiment, the ratio of NEPI regions 304 to PEPI region 302 is 2:1. In an embodiment, a device region adjacent the dummy region of the layout 700 may include a NEPI region 304 to PEPI region 302 ratio of 1:2, with the NEPI and PEPI configuration swapped in array positions between the device region and the dummy region.

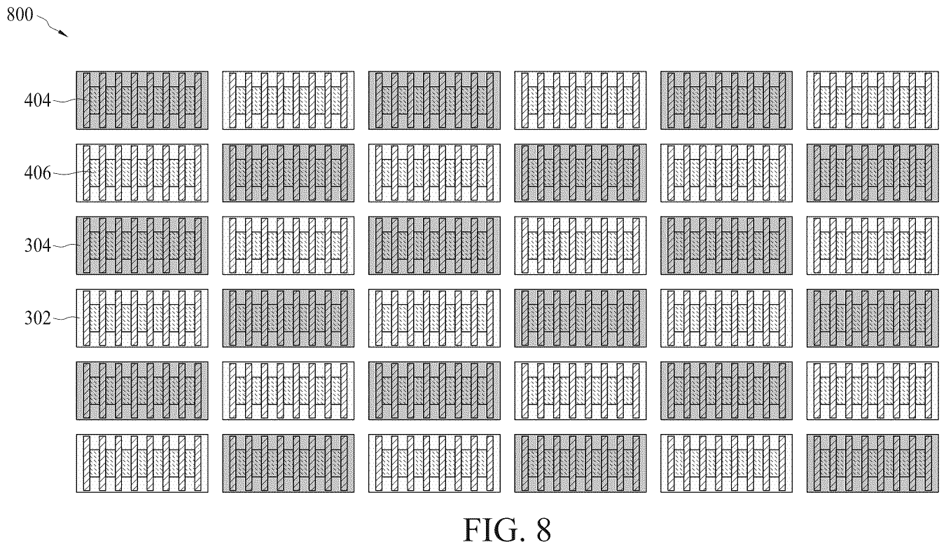

In FIG. 8, the layout 800 illustrates a dummy region having a first plurality of PEPI regions 302 and a second plurality of NEPI regions 304. The first plurality of PEPI regions 302 is equal in number than the second plurality of NEPI regions 304. In an embodiment, the ratio of PEPI regions 302 to NEPI region 304 is 1:1. In an embodiment, the layout 800 includes an alternating PEPI region 302 and NEPI region 304 along a row and along a column of an array. In an embodiment, a device region adjacent the dummy region of the layout 800 may include a NEPI region 304 to PEPI region 302 ratio of 1:1, with the NEPI and PEPI configuration swapped in array positions between the device region and the dummy region.

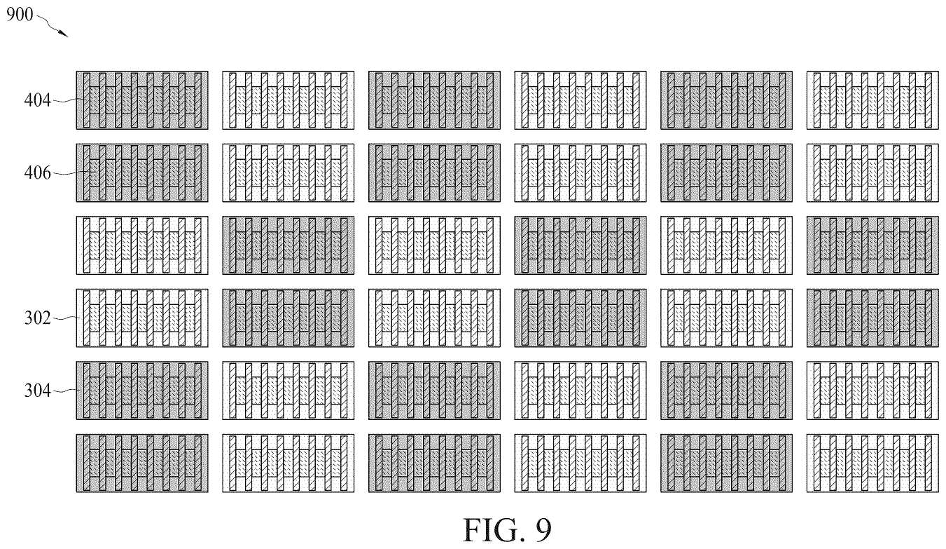

In FIG. 9, the layout 900 illustrates a dummy region having a first plurality of PEPI regions 302 and a second plurality of NEPI regions 304. The first plurality of PEPI regions 302 is equal in number than the second plurality of NEPI regions 304. In an embodiment, the ratio of PEPI regions 302 to NEPI region 304 is 1:1. In an embodiment, the layout 900 includes two PEPI region 302 followed by two NEPI region 304 along a column. In an embodiment, the layout 900 includes a PEPI region 302 followed by an NEPI region 304 along a row. In an embodiment, a device region adjacent the dummy region of the layout 700 may include a NEPI region 304 to PEPI region 302 ratio of 1:1, with the NEPI and PEPI configuration swapped in array positions between the device region and the dummy region.

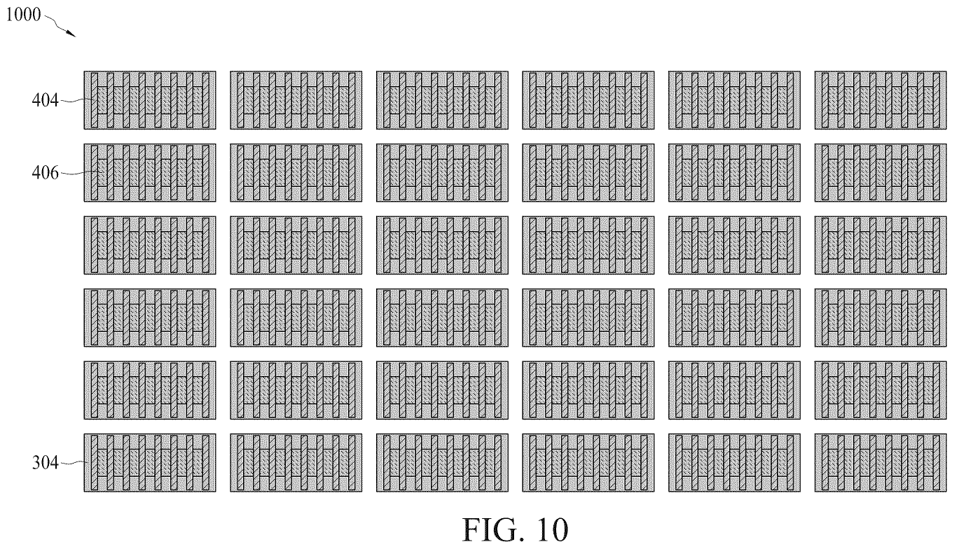

In FIG. 10, the layout 1000 illustrates a dummy region having a plurality of NEPI regions 304. In an embodiment, the layout 1000 does not include PEPI regions 302. In an embodiment, a device region adjacent the dummy region of the layout 1000 may include NEPI regions 304 and PEPI regions 302 such as for example as illustrated in FIGS. 3A and 3B.

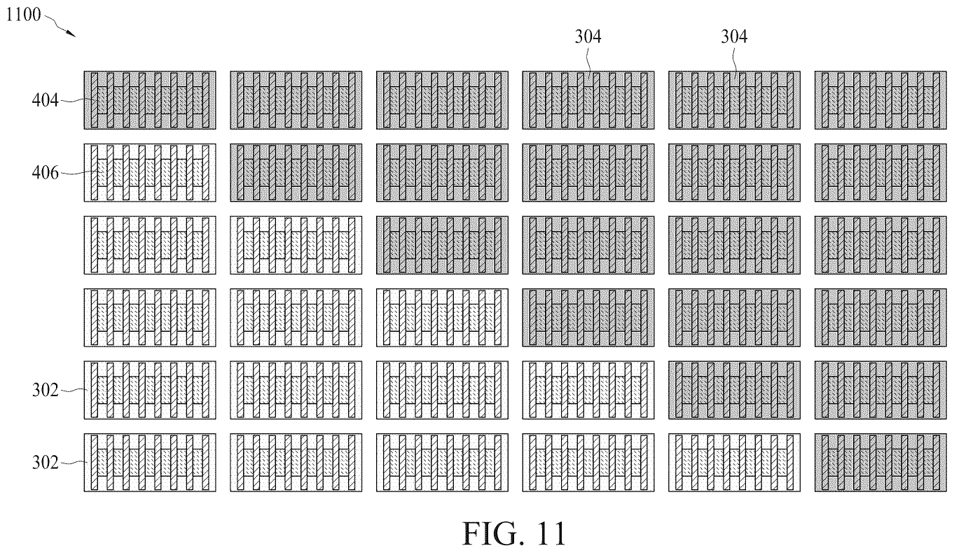

In FIG. 11, the layout 1100 illustrates a dummy region having a first plurality of PEPI regions 302 and a second plurality of NEPI regions 304. In an embodiment, the ratio of NEPI regions 304 to PEPI region 302 is greater than 2:1. In an embodiment, the ratio of NEPI regions 304 to PEPI region 302 is between approximately 2:1 to 1:2 In a further embodiment, the ratio of NEPI regions 304 to PEPI region 302 is 2:1. In a further embodiment, the ratio of NEPI regions 304 to PEPI region 302 is 1:2. In an embodiment, the layout 1100 has a non-uniform configuration. In an embodiment, a device region adjacent the dummy region of the layout 1000 may include NEPI regions 304 and PEPI regions 302 such as for example as illustrated in FIGS. 3A and 3B.

In some implementations, the dummy region includes approximately 50% regions of a first dopant type and approximately 50% regions of a second dopant type (e.g., 50% PEPI and 50% NEPI).

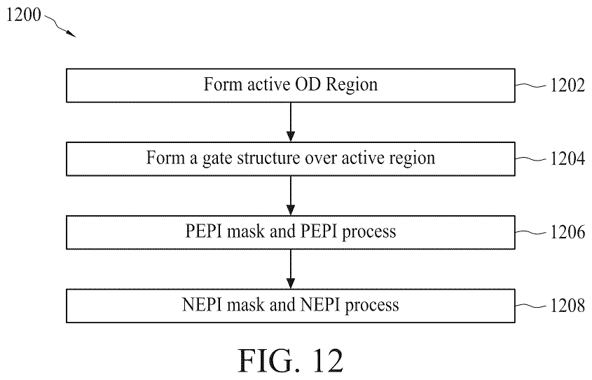

FIG. 12 illustrates a method 1200 that may be implemented to form a semiconductor structure. In an embodiment, the semiconductor structure is a chip and in particular, an integrated circuit (IC) chip. The method 1200 may be implemented after a layout for the semiconductor structure has been determined as discussed above, including with respect to the method 100 of FIG. 1. The method 1200 is merely exemplary and are not intended to limit the present disclosure to what is explicitly illustrated therein. Additional steps may be provided before, during and after the method 1200, and some steps described can be replaced, eliminated, or moved around for additional embodiments of the methods. Not all steps are described herein in detail for reasons of simplicity.

In a first block 1202, active or OD regions are formed on a substrate. The active or OD regions are formed on a device region of the substrate and a dummy region of the substrate. The device regions may include active devices such as n-type transistors and p-type transistors interconnected to form a semiconductor device. The dummy regions may include features corresponding to those in the device regions but do not provide electrical functionality to the semiconductor device.

In an embodiment, the active OD regions are planar portions of a semiconductor substrate. In an embodiment, the active OD regions are fin elements extending above a substrate such as illustrated in OD regions 406 of FIGS. 4C and 4D. In an embodiment, the active OD regions include nanowire, nanobar, or nanosheet, all collectively referred to as nanostructures. The nanostructures may be used to form channel regions of gate-all-around (GAA) devices. Isolation features such as shallow trench isolation (STI) or field oxide (FOX) are formed between the active OD regions. The isolation features may be substantially similar to the isolation features 402 discussed above.

The method 1200 then proceeds to block 1204 where a gate structure is formed over the active OD regions. The gate structure may include a gate stack substantially similar to the gate structure 404 discussed above. In some implementations, the gate structure includes gate dielectric and electrode. The gate structure formed in block 1204 may be a dummy gate structure that is in later process steps removed to form a trench within which a functional gate is formed. In such a case, the gate stack as formed in block 1204 may be a polysilicon gate.

The method 1200 then proceeds to blocks 1206 and 1208 where source/drain features are formed. The source/drain features may be epitaxial regions such as epitaxial regions 408 and 410 discussed above with reference to FIGS. 4C, and 4D.

In an embodiment, a first masking layer is formed on the substrate where the first masking layer includes a plurality of openings defining regions of a first doping type (e.g., p-type). The openings are aligned with regions were a source/drain feature of a first dopant type is to be grown on the active OD region in the device regions and the dummy regions of the substrate. In an embodiment, the plurality of openings of the masing layer may be substantially similar to the PEPI regions 302 discussed above.

While maintaining the first masking element, CVD deposition techniques (e.g., vapor-phase epitaxy (VPE) and/or ultra-high vacuum CVD (UHV-CVD)), molecular beam epitaxy (MBE), and/or other suitable processes are performed to form epitaxial regions of a first dopant type. The epitaxial growth process may use gaseous and/or liquid precursors, which interact with the composition of the active OD regions of block 1202. In various embodiments, the p-type epitaxial features may include Si, Ge, AlGaAs, SiGe, boron-doped SiGe (SiGeB), or other suitable material. The p-type epitaxial features may be in-situ doped during the epitaxial process by introducing doping species including p-type dopants, such as boron or BF₂, and/or other suitable dopants including combinations thereof. In some implementations, an implantation process may be performed to dope the p-type epitaxial features.

The method then proceeds to block 1208 where, after removal of the first masking element of block 1206, a second masking element is formed on the substrate where the second masking layer includes a plurality of openings defining regions of a second doping type (e.g., n-type). The openings are aligned with regions were a source/drain feature of a second dopant type is to be grown on the active OD region in the device regions and the dummy regions of the substrate. In an embodiment, the plurality of openings may be substantially similar to the NEPI regions 304 discussed above.

While maintaining the second masking element, CVD deposition techniques (e.g., vapor-phase epitaxy (VPE) and/or ultra-high vacuum CVD (UHV-CVD)), molecular beam epitaxy (MBE), and/or other suitable processes are performed to form epitaxial regions of a first dopant type. The epitaxial growth process may use gaseous and/or liquid precursors, which interact with the composition of the active OD regions of block 1202.

Suitable epitaxial processes for forming second type of epitaxial features may be similar to the epitaxial processes for forming first type of epitaxial source/drain features. In various embodiments, the n-type epitaxial features may be formed that include Si, GaAs, GaAsP, SiP, or other suitable material. The n-type epitaxial features may be in-situ doped during the epitaxial process by introducing doping species including n-type dopants, such as phosphorus or arsenic; and/or other suitable dopants including combinations thereof. In some implementations, an implantation process may be performed to dope the n-type epitaxial features.

Block 1208 then continues to other semiconductor fabrication processes. In some implementations, dielectric materials such as insulation region 412 are formed over the substrate. The gate structure of block 1204 may be removed and replaced with a high-k dielectric gate oxide and metal gate electrode gate stack. Various other features including MLI such as contacts, metal lines and interposing vias are formed.

FIG. 13 is a block diagram of a hardware system 1300 for implementing the methods and layout embodiments described with references to FIGS. 1-12 in accordance with some embodiments. The system 1300 includes at least one processor 1302, a network interface 1304, an input and output (I/O) device 1306, a storage 1308, a memory 1312, and a bus 1310. The bus 1310 couples the network interface 1304, the I/O device 1306, the storage 1308 and the memory 1312 to the processor 1302.

In some embodiments, the memory 1312 comprises a random access memory (RAM) and/or other volatile storage device and/or read only memory (ROM) and/or other non-volatile storage device. The memory 1312 includes a kernel and user space, configured to store program instructions to be executed by the processor 1302 and data accessed by the program instructions.

In some embodiments, the network interface 1304 is configured to access program instructions and data accessed by the program instructions stored remotely through a network. The I/O device 1306 includes an input device and an output device configured for enabling user interaction with the system 1300. The input device comprises, for example, a keyboard, a mouse, etc. The output device comprises, for example, a display, a printer, etc. The storage device 1308 is configured for storing program instructions and data accessed by the program instructions. The storage device 1308 comprises, for example, a magnetic disk and an optical disk.

In some embodiments, when executing the program instructions, the processor 1302 is configured to perform the method 100 and/or provide the layouts described above. In some embodiments, the program instructions are stored in a non-transitory computer readable recording medium such as one or more optical disks, hard disks and non-volatile memory devices. In some embodiments, a file containing the layouts described above is stored in a non-transitory computer-readable storage medium.

Based on the above descriptions, it can be seen that the present disclosure offers advantages over conventional methods and semiconductor structures. It is understood, however, that other embodiments may offer additional advantages, and not all advantages are necessarily disclosed herein, and that no particular advantage is required for all embodiments. For example, the present disclosure provides for systems, structures, layouts and methods that allow for a chip to have an improved n-type epitaxial region (e.g., n-type source/drain) critical dimension in terms of CD value and/or uniformity (CDU). The NEPI regions of a dummy area of a semiconductor structure may be selected and arranged (e.g., tuned) based on the active area design to provide for improved CD and CDU.

The present disclosure provides for many different embodiments. Semiconductor structures, semiconductor structure designs, methods of designing a semiconductor structure layout, and methods of fabrication thereof are disclosed herein. In one exemplary aspect, the present disclosure is directed to a semiconductor structure including a substrate having a device region and a dummy region. A first active region is disposed over the substrate in the device region and a second active region is over the substrate in the dummy region. A first operational gate structure over the first active region and a first non-operational gate structure over the second active region. A first epitaxial region of an n-type dopant is adjacent the first operation gate structure; and a second epitaxial region of an n-type dopant is adjacent the first non-operational gate structure.

In an embodiment, the first active region is a first fin element and the second active region is a second fin element. In an embodiment, the first active region is a first plurality of nanostructures and the second active region is a second plurality of nanostructures. In some implementations, the structure may further comprise a third active region over the substrate in the device region and a fourth active region over the substrate in the dummy region, a second operational gate structure over the third active region, a second non-operational gate structure over the third active region, a third epitaxial region of a p-type dopant adjacent the second operation gate structure; and a fourth epitaxial region of an n-type dopant adjacent the second non-operational gate structure.

In an embodiment of the structure, a first array of cells are included in the device region and a second array of cells are included in the dummy region. And the first active region forms a first cell of the first array of cells and the second active region forms a first cell of the second array of cells. In an embodiment, the second epitaxial region is formed on the second active region. The first active region may be formed of nanosheets.

In another of the broader embodiments, a semiconductor structure includes a substrate including a device region and a dummy region and a plurality of NEPI regions in the dummy region. The plurality of NEPI regions includes an active region extending in a first direction, a plurality of gate structures extending in a second direction, and an n-type doped epitaxial region. A plurality of NEPI regions are in the device region. The plurality of NEPI regions includes an active region extending in the first direction, a plurality of gate structures extending in the second direction, and an n-type doped epitaxial region.

In a further embodiment, the dummy region further includes a plurality of PEPI regions. In an embodiment, the dummy region a total number of the plurality of the NEPI regions is greater than a total number of the plurality of PEPI regions. In an embodiment, the plurality of NEPI regions are configured in a first column of an array of regions and the first column includes a first NEPI region, a next adjacent second NEPI region, and a next adjacent first PEPI region. In another embodiment, the dummy region includes alternating arrangement of the plurality of NEPI regions and the plurality of PEPI regions. In some implementations, the dummy region includes an array of the plurality of NEPI regions and the plurality of PEPI regions, wherein in a first column of the array includes in order a first NEPI region of the plurality of NEPI regions, a second NEPI region of the plurality of NEPI regions, and a first PEPI region of the plurality of PEPI regions. In an embodiment, the active region includes an another array of the plurality of NEPI regions and the plurality of PEPI regions. A first column of the another array may include in order a second PEPI region of the plurality of PEPI regions, a third PEPI region of the plurality of PEPI regions, and a second NEPI region of the plurality of NEPI regions. In a further embodiment, the first NEPI region of the dummy region and the second PEPI region of the active region are aligned in a same row. In an embodiment, the isolation region is between the second PEPI region and the third PEPI region.

In another of the broader embodiments, a method includes providing a substrate having a dummy region and a device region, forming a first active region in the dummy region and a second active region in the device region, and forming gate structures over the substrate. A first plurality of gate structures extends over the first active region in the dummy region and a second plurality of gate structures extends over the second active region in the device region. The method also includes providing a first masking element with a first set of openings over the dummy region and the device region and growing a first plurality of epitaxial regions having a first dopant type in the dummy region and the device region while the providing the first masking element. A second masking element is provided with a second set of openings over the dummy region and the device region. And a second plurality of epitaxial regions is grown having a second dopant type in the dummy region and the device region while the providing the second masking element.

In a further embodiment of the method, after growing the first plurality and the second plurality of epitaxial regions, the gate structures are replaced with gate stacks of a high-k gate dielectric and metal gate electrode. In an embodiment, the first active region is formed by forming a fin element in the dummy region and the forming of the second active region comprises forming a fin element in the device region. In an embodiment, the method also includes determining openings of the first masking element in the dummy region based on the openings of the first masking element in the device region.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a dummy region of the semiconductor device having an array arrangement of a first type of regions and a second type of regions,
wherein each of the first type of regions includes:
a first plurality of gate structures extending in a first direction in a top view;
a first active region extending in a second direction in the top view, the first plurality of gate structures extending over the first active region; and
a first plurality of epitaxial regions formed on the first active region between each of the first plurality of gate structures, wherein the first plurality of epitaxial regions is a first conductivity type;
wherein each of the second type of regions includes:
a second plurality of gate structures extending in the first direction in a top view;
a second active region extending in the second direction in the top view, the second plurality of gate structures extending over the second active region; and
a second plurality of epitaxial regions formed on the second active region between each of the second plurality of gate structures, wherein the second plurality of epitaxial regions is a second conductivity type, the second conductivity type being one of n-type or p-type and the first conductivity type being the other one of n-type or p-type.

2. The semiconductor device of claim 1, wherein an epitaxial feature of the first conductivity type is lacking in each of the second type of regions.

3. The semiconductor device of claim 1, wherein an epitaxial feature of the second conductivity type is lacking in each of the first type of regions.

4. The semiconductor device of claim 1, wherein each of the first plurality of epitaxial regions is not electrically connected to another feature.

5. The semiconductor device of claim 4, wherein each of the second plurality of epitaxial regions is not electrically connected to another feature.

6. The semiconductor device of claim 1, wherein in the top view, a first column of the array arrangement includes the first type of regions and the second type of regions in a 2:1 ratio.

7. The semiconductor device of claim 6, wherein in the top view, the first column of the array arrangement includes, in order, two of the first type of regions, two of the second type of regions, and two of the first type of regions.

8. The semiconductor device of claim 6, wherein in the top view, the first column of the array arrangement includes, in order, one of the second type of regions, two of the first type of regions, one of the second type of regions, and two of the first type of regions.

9. The semiconductor device of claim 1, wherein in the top view, a device region of the semiconductor device has another array arrangement of the first type of regions and the second type of regions.

10. The semiconductor device of claim 9, wherein the dummy region includes a first array arrangement having the first type of regions and the second type of regions at a first ratio of 2:1, and the device region includes a second array arrangement having the first type of regions and the second type of regions at a second ratio of 1:2.

11. A semiconductor structure, comprising:
a substrate including a device area and a dummy area;
a first array including a first type of regions and a second type of regions in the device area;
a second array including the first type of regions and the second type of regions in the dummy area;
wherein each of the first type of regions includes:
a first plurality of gate structures extending in a first direction in a top view;
a first active region extending in a second direction in the top view, the first plurality of gate structures extending over the first active region; and
a first plurality of epitaxial regions formed on the first active region between gate structures of the first plurality of gate structures, wherein the first plurality of epitaxial regions is a first conductivity type;
wherein each of the second type of regions include:
a second plurality of gate structures extending in the first direction in a top view;
a second active region extending in the second direction in the top view, the second plurality of gate structures extending over the second active region; and
a second plurality of epitaxial regions formed on the second active region between gate structures of the second plurality of gate structures, wherein the second plurality of epitaxial regions is a second conductivity type, the second conductivity type being one of n-type or p-type and the first conductivity type being the other one of n-type or p-type.

12. The semiconductor structure of claim 11, wherein the first array includes a ratio of the first type of regions to the second type of regions of 2:1, and the second array includes a ratio of the first type of regions to the second type of regions of 1:2.

13. The semiconductor structure of claim 11, wherein a first row of the first array in the device area is aligned with a first row of the second array in the dummy area, to form a combined first row, the combined first row including alternating first type of regions and second type of regions.

14. The semiconductor structure of claim 13, wherein a second row of the first array in the device area is aligned with a second row of the second array in the dummy area, to form a combined second row, the combined second row including alternating second type of regions and first type of regions.

15. The semiconductor structure of claim 11, wherein the first active region is a first plurality of nanostructures and the second active region is a second plurality of nanostructures.

16. A semiconductor structure, comprising:
an array of a first type of regions and a second type of regions in a dummy area of the semiconductor structure;
wherein each of the first type of regions includes:
a first plurality of gate structures extending in a first direction in a top view;
a first active region extending in a second direction in the top view, the first plurality of gate structures extending over the first active region; and
a first plurality of epitaxial regions formed on the first active region between gate structures of the first plurality of gate structures, wherein the first plurality of epitaxial regions is a first conductivity type;
wherein each of the second type of regions includes:
a second plurality of gate structures extending in the first direction in a top view;
a second active region extending in the second direction in the top view, the second plurality of gate structures extending over the second active region; and
a second plurality of epitaxial regions formed on the second active region between gate structures of the second plurality of gate structures, wherein the second plurality of epitaxial regions is a second conductivity type, the second conductivity type being one of n-type or p-type and the first conductivity type being the other one of n-type or p-type; and
an isolation region interposing each of the first type of regions and the second type of region,
wherein for a first one of the first type of regions and a first one of the second type of regions, a first gate structure of the first plurality of gate structures is collinear with a second gate structure of the second plurality of gate structures and the first active region is parallel to the second active region.

17. The semiconductor structure of claim 16, further comprising:
a second one of the first type of regions interposing the first one of the first type of regions and the first one of the second type of regions.

18. The semiconductor structure of claim 16, wherein each first active region of the first type of regions and each second active region of the second type of regions includes fins.

19. The semiconductor structure of claim 16, wherein each first active region of the first type of regions and each second active region of the second type of regions include a vertical stack of nanostructures.

20. The semiconductor structure of claim 16, further comprising:
another array of the first type of regions and the second type of regions in a device area of the semiconductor structure adjacent the dummy area, wherein the array and the another array differ in arrangement.
